(19) United States
(12) Patent Application Publication
(10) Pub. No.: US 2008/0286967 A1
(43) Pub. Date: Nov. 20, 2008

(54) METHOD FOR FABRICATING A BODY TO SUBSTRATE CONTACT OR TOPSIDE SUBSTRATE CONTACT IN SILICON-ON-INSULATOR DEVICES

(75) Inventors: Mark A. Good, Colorado Springs, CO (US); Craig Schwechel, Glen Allen, VA (US)

Correspondence Address: SCHWEGMAN, LUNDBERG & WOESSNER / ATMEL, P.O. BOX 2938, MINNEAPOLIS, MN, 55402, US

(73) Assignee: Atmel Corporation, San Jose, CA (US)

(21) Appl. No.: 11/750,485

(22) Filed: May 18, 2007

(51) Int. Cl. H01L 21/44

(52) U.S. Cl. 438/671; 438/669; 257/E21.476

(57) ABSTRACT

A method of forming an electrical contact between an active semiconductor device layer and a base substrate. The method includes forming a first masking layer over an uppermost surface of the active semiconductor layer, patterning a window in the masking layer, and etching an opening down to the base substrate within an area defined by the window. The opening is filled with a semiconductor contact material while simultaneously adding a dopant to the semiconductor contact material thereby forming an electrical contact between the active semiconductor device layer and the base substrate.

### TECHNICAL FIELD

The present invention relates to a method of fabricating a semiconductor device, and more particularly, to a body-to-substrate contact structure for a silicon-on-insulator (SOI) semiconductor device and method of fabricating the same.

### BACKGROUND ART

Silicon-on-insulator (SOI) devices are becoming the most common structure for new semiconductor designs. The SOI devices have the advantage of excellent electrical isolation between adjacent devices fabricated thereon. The structure is generally a silicon substrate having an overlying insulator with an overlying active layer. The devices are fabricated in the overlying active layer. Isolation of the active layer prevents or minimizes any electrical effects between adjacent active areas.

SOI devices have various advantages as compared to a semiconductor device fabricated on bulk silicon substrate. Due to the electrical isolation of SOI devices, a source/drain capacitance is reduced. The SOI fabricated device performs a high speed circuit operation well, has a high reliability of isolation between devices, and has a strong resistance to soft errors due to alpha particles.

However, SOI devices share a common disadvantage. The silicon bulk substrate may be connected to the ground voltage to maintain a fixed voltage, but the semiconductor device layer is isolated from the silicon bulk substrate and is thus floating. Therefore, a potential value of the semiconductor device layer varies according to the variation of voltage applied to the source/drain. As a result, a floating body effect may make the device functionality unstable.

For example, when a high voltage is applied to the drain, a high electric field occurs. The high electric field causes impact ionization which generates electron-hole pairs around the drain. The holes of the generated electron-hole pairs are injected into and positively charge the semiconductor device layer. With a positively charged semiconductor device layer, the potential of the device layer increases and causes variation of the threshold voltage. Accordingly, a kink is shown on a drain current-voltage curve, thereby detrimentally affecting device performance.

Additionally, as the potential of the semiconductor device layer increases, a source-body junction (e.g., an emitter-base junction) becomes more forwardly biased. The forward bias condition injects electrons from the source toward the device layer. The electrons injected into the body layer increase drain current by reaching a drain depletion region. Thus, a parasitic bipolar effect occurs which disables the control of drain-source current (I_{ds}) by a gate electrode.

Thus, the most serious problem in fabricating a SOI device is the floating body effect. To disable the floating body effect, the semiconductor device layer must be connected to a fixed voltage. However, it is not easy to connect the semiconductor body layer to a fixed voltage source because the semiconductor substrate and the semiconductor body layer are electrically isolated from each other by an intervening dielectric layer. To eliminate the floating body effect, an electrical contact is typically formed from the semiconductor device layer to the bulk substrate.

There are two basic approaches generally used to fabricate the electrical contact. One approach uses a backside contact, which contacts the backside of semiconductor dice on the semiconductor device layer; the other approach uses a frontside contact, which is achieved through contact with an uppermost side of the semiconductor dice containing active circuitry. Each of these techniques have varying types of difficulties involved in fabrication. For the frontside contact, one difficulty is having a sufficiently low resistance electrical contact to the substrate. Another difficulty is that other devices may be adversely affected while forming an effective contact to the substrate. Further, fabrication of the electrical contact involves a number of costly and time-consuming fabrication steps. Some of these steps, such as a required high temperature anneal step, can have deleterious effects on electrical device performance.

The backside contact involves utilizing a packaging-type contact in which the package itself makes contact with the backside of the silicon substrate. Although this is effective, it also has been found to be quite expensive.

With reference to FIG. 1, a prior art SOI device 100 comprised of a substrate 101 having an electrical contact region 103. The SOI device 100 further includes an dielectric layer 105, an active device layer having a source region 111 and a drain region 113 for a transistor device 150, and an isolation region 109. The isolation region 109 is adjacent to the source region ill and both overlie the dielectric layer 105. The electrical contact region 103 is typically formed by a blanket implant of boron at a high energy of 100 KeV. A result of the implanted boron is a heavily doped contact region 103 which is under the dielectric layer 105 throughout a particular semiconductor wafer.

A first silicon contact plug 107 electrically contacts the substrate 101 through the electrical contact region 103 by photolithographically patterning and then etching through the plurality of layers until the electrical contact region 103 is reached. A second silicon contact plug 115 similarly provides a contact point from an uppermost surface of the prior art SOI device 100 to the drain region 113. After etching, the silicon contact plugs were formed by filling a series of aligned etched holes with a silicon deposition producing the silicon contact plugs 107, 115. The silicon contact plugs 107, 115 are then subjected to a high energy, high concentration dopant implant to make the silicon conductive. The silicon contact plugs are then subjected to a high temperature anneal step to evenly distribute dopant atoms to reduce high resistance implant profile tails. The required high temperature anneal may adversely affect device performance by, for example, diffusing dopant atoms in the source 111 and drain 113 regions. However, without the anneal step, the silicon contact plugs 107, 115 may have high resistance contact problems.

Thus, there is a need for an electrical contact between an active semiconductor device layer and a bulk substrate in SOI applications that avoids the problems of adversely affecting formed electrical devices while having a sufficiently conductive contact. Also, formation of the electrical contact should minimize additional fabrication steps and processes.

### SUMMARY

In an exemplary embodiment, the invention is a method of forming an electrical contact to a base substrate having a first conductivity type. The method includes providing the base substrate having a dielectric layer and an active semiconductor layer formed thereon with the dielectric layer arranged to electrically insulate the active semiconductor layer from the base substrate. A first masking layer is formed over an uppermost surface of the active semiconductor layer. A window is patterned on the first masking layer and a first opening is etched through the first masking layer to the underlying active semiconductor layer within an area defined by the window. A second opening is etched through an exposed region of the active semiconductor layer to the dielectric layer within the area defined by the window and a third opening is etched through an exposed region of the dielectric layer to the base substrate. The first, second, and third openings are filled with a semiconductor contact material while simultaneously adding a dopant, having the first conductivity type, to the semiconductor contact material. The semiconductor contact layer is in electrical contact with the base substrate.

In another exemplary embodiment, the invention is a method of forming an electrical contact to a base substrate in a silicon-on-insulator (SOI) material. The method includes forming a first masking layer over an uppermost surface of an active semiconductor layer. The active semiconductor layer has a first conductivity type and is an uppermost portion of the silicon-on-insulator material. A window is patterned on the first masking layer and a first opening is etched through the first masking layer to the active semiconductor layer within an area defined by the window. A second opening is etched through an exposed region of the active semiconductor layer to a dielectric layer within the area defined by the window. The dielectric layer being a second portion of the silicon-on-insulator material. A third opening is etched through an exposed region of the dielectric layer to a base substrate of the silicon-on-insulator material. The base substrate has the first conductivity type. The first, second, and third openings are filled with a semiconductor contact material while simultaneously adding a dopant, having the first conductivity type, to the semiconductor contact material. The semiconductor contact layer is in electrical contact with the base substrate.

In another exemplary embodiment, the invention is a method of forming an electrical contact to a base substrate in a silicon-on-insulator (SOI) material. The method includes forming a first masking layer over an uppermost surface of an active semiconductor layer. The active semiconductor layer is an uppermost portion of the silicon-on-insulator material. A window is patterned on the first masking layer and a first opening is etched through the first masking layer to the active semiconductor layer within an area defined by the window. A second opening is etched through an exposed region of the active semiconductor layer to a dielectric layer within the area defined by the window. The dielectric layer being a second portion of the silicon-on-insulator material. A third opening is etched through an exposed region of the dielectric layer to a base substrate of the silicon-on-insulator material. The base substrate has the first conductivity type. The first, second, and third openings are filled with a semiconductor contact material while simultaneously adding a dopant, having the first conductivity type, to the semiconductor contact material. The semiconductor contact layer is in electrical contact with the base substrate.

### BRIEF DESCRIPTION OF THE DRAWINGS

FIG. 1 is a cross-sectional drawing of a prior art SOI front-side contact to a substrate.

FIGS. 2A-2I are cross-sectional drawings at various fabrication stages of an exemplary SOI front-side contact to a substrate in accordance with the present invention.

### DETAILED DESCRIPTION

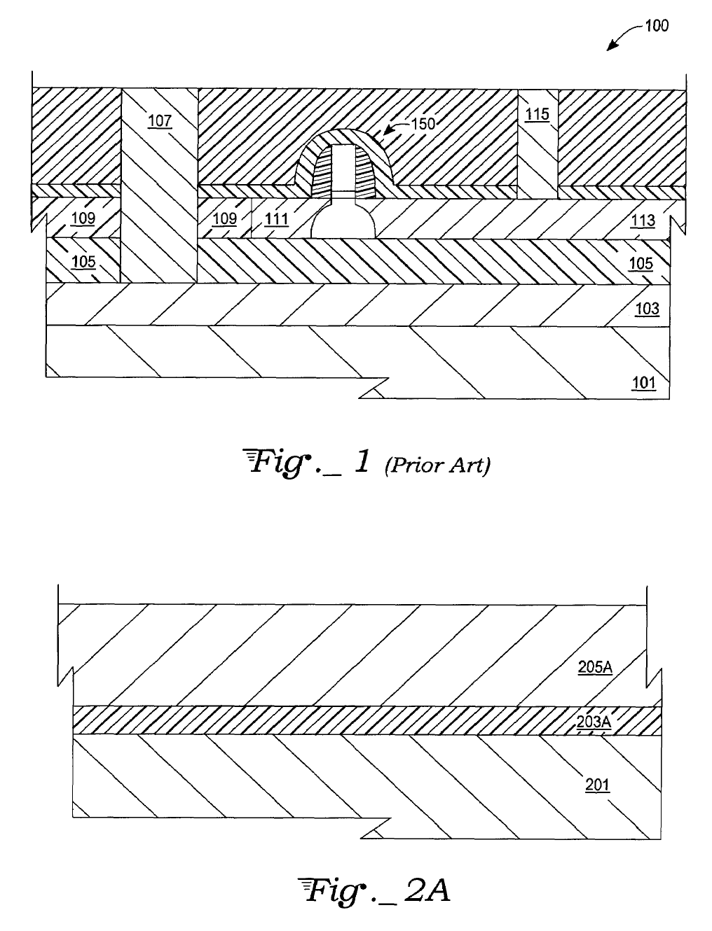

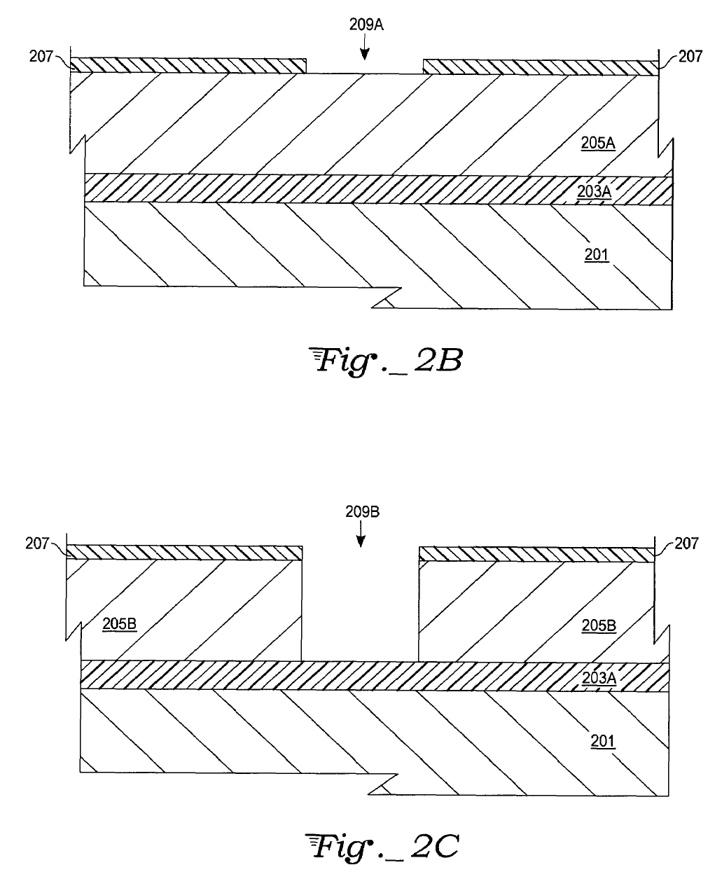

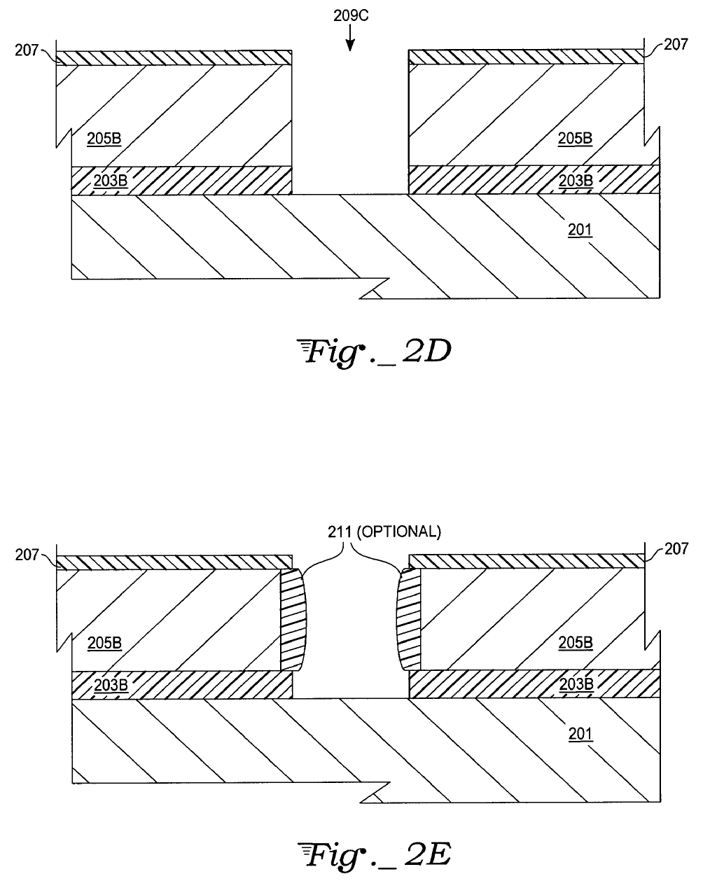

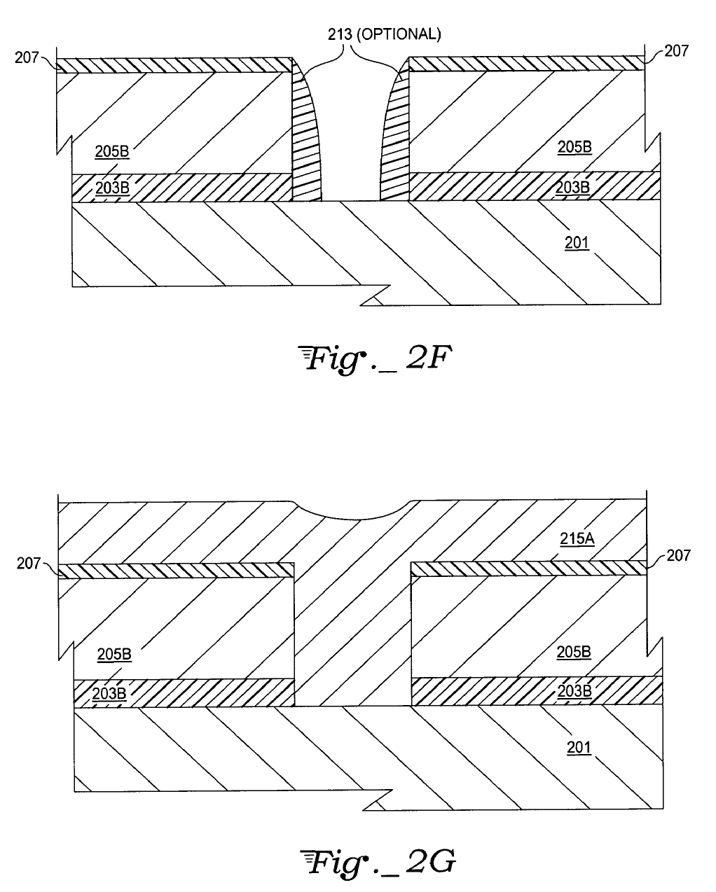

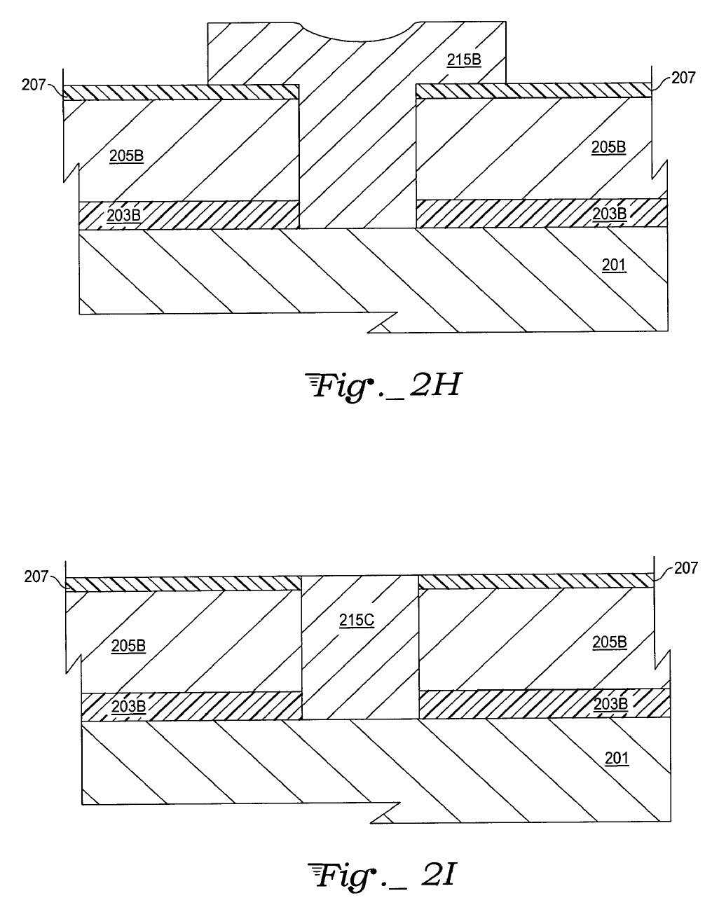

With reference to FIG. 2A, an exemplary SOI substrate includes a base substrate 201, an insulating layer 203A, and a active semiconductor layer 205A. In a specific exemplary embodiment, the base substrate 201 is a silicon wafer. Alternatively, the base substrate 201 may be comprised of another elemental Group IV semiconductor, or a compound semiconductor (e.g., Group III-V) may be selected. In a case where the base substrate 201 is a semiconductor wafer, the wafer may contain a buried oxide layer (not shown) placed below a polysilicon layer (not shown) to prevent transport of carriers through the underlying bulk semiconducting material. The polysilicon is then treated at an elevated temperature to reform crystalline (i.e., non-amorphous) silicon. In still another embodiment, the base substrate 201 is formed from intrinsic silicon, thereby effectively limiting transport of carriers due to the high resistivity of intrinsic silicon.

The insulating layer 203A may be a deposited silicon dioxide (SiO₂) layer. The insulating layer 203A may be deposited, thermally grown, or formed by oxygen implantation. In other embodiments, the insulating layer 203A may be comprised of insulators such as silicon nitride (Si₃N₄), sapphire, or various other insulative materials known in the art.

In FIG. 2B, a patterned masking layer 207 has been formed on an uppermost surface of the active semiconductor layer 205A. The patterned masking layer may be comprised of formed and patterned photoresist, silicon dioxide (either thermally grown or deposited via, for example, chemical vapor deposition (CVD)), silicon nitride, or combinations of these and other masking materials. A first window 209A indicates an area in which subsequent etching will occur.

Portions underlying the first window 209A may be either wet or dry etched creating an etched active semiconductor layer 205B (FIG. 2C) and a resulting larger second window 209B. In a specific exemplary embodiment, a reactive ion etch (RIE) process is used to etch exposed areas of the active semiconductor layer 205A (FIG. 2B). The RIE is an anisotropic etch which leaves essentially only vertical sidewalls on the etched active semiconductor layer 205B. In another specific exemplary embodiment where the semiconductor layer is comprised of silicon, various wet etchant types may be employed. For example, aqueous alkaline solutions are commonly used anisotropic silicon etchants. Two categories of aqueous alkaline solutions which may be employed are: (1) pure inorganic aqueous alkaline solutions such as potassium hydroxide (KOH), sodium hydroxide (NaOH), cesium hydroxide (CsOH), and ammonium hydroxide (NH₄OH); and (2) organic alkaline aqueous solutions such as ethylenediamine-pyrocatechol-water (aqueous EDP), tetramethyl ammonium hydroxide (TMAH or (CH₃)₄NOH) and hydrazine (H₄N₂). Other aqueous solutions may be employed in other embodiments.

Once the etched active semiconductor layer 205B is formed, another etchant may be used to form an etched insulating layer 203B (FIG. 2D) and a resulting larger third window 209C. For example, if the insulating layer 203A (FIG. 2C) is comprised of silicon dioxide, a wet chemical etchant such as hydrofluoric acid (commonly contained in a standard buffered oxide etch (BOE)), or orthophosphoric acid, or alternatively a selective dry etch technique (e.g., reactive-ion-etching (RIE)) may all be used to create the etched insulating layer 203B.

With reference to FIG. 2E, in a specific exemplary embodiment, an optional liner 211 may be added in situations where electrical contact with the etched active semiconductor layer 205B should be avoided. The optional liner 211 may be, for example, formed by thermally growing a silicon dioxide layer over a silicon active layer. In other embodiments, the optional liner 211 may be formed from another dielectric material known in the art followed by a high selectivity etchant. Any dielectric material formed over the base substrate 201 will be removed by, for example, an anisotropic etch prior to subsequent processing steps.

In FIG. 2F, in another specific exemplary embodiment, an optional dielectric spacer 213 is formed to prevent electrical contact with the etched active semiconductor layer 205B. Formation of the optional dielectric spacer 213 is known in the art. As with the specific exemplary embodiment described with reference to FIG. 2E, any dielectric material formed over the base substrate 201 will be removed to insure proper electrical contact in subsequent process steps.

Prior to subsequent fabrication steps (i.e., after either forming the etched insulating layer 203B or forming either the optional liner 211 or the optional dielectric spacer 213), a cleaning step (e.g., a wet clean or other cleans, such as a hydrogen reduction process) is typically performed. In general terms, if any surface is not sufficiently clean prior to growth or deposition of surface-critical films, contact/via resistances may be too high, poor adhesion between layers of material may result wherein IC reliability is reduced, retarded film formation may occur (e.g., a silicide may never properly form), and/or poor texture (e.g., microroughness) and/or grain structure may result in the film.

A typical wet cleaning operation uses various aqueous-based chemicals. Wet cleaning chemicals frequently contain various combinations of hydrofluoric or hydrochloric acid, ammonium hydroxide, ammonium fluoride, hydrogen fluoride, or hydrogen peroxide. Part of the cleaning process will remove formed native oxide. Even though the native oxide is thin (typically 8 Å-20 Å depending upon exposure time, presence of oxygen or water vapor, ambient temperature, etc.), the oxide is invariably non-uniform. Consequently, subsequent film formation steps may be adversely affected. Thus, a wet clean operation better prepares the underlying base substrate 201 for improved electrical performance. Further, if neither the optional liner 211 (FIG. 2E) nor the optional dielectric spacer 213 (FIG. 2F) is used, the etched active semiconductor layer 205B is also cleaned for enhanced electrical performance.

Referring now to FIG. 2G, an in-situ doped layer 215A is blanket deposited. The in-situ doped layer 215A may be, for example, a polysilicon or amorphous silicon layer. The in-situ doped layer 215A is thick enough to fill the width of the area in contact with the base substrate 201 and any exposed areas of the etched active semiconductor layer 205B. The in-situ doped layer 215A may be deposited with an n-type dopant (using, for example, arsenic or phosphorous) if the base substrate 201 is doped n-type. Alternatively, if the base substrate 201 is doped p-type, then a p-type dopant (using, for example, boron or gallium) may be deposited with the in-situ doped layer 215A. Generally, the conductivity type of any of the semiconducting layers should be selected to be the same if they are to be in electrical contact with one another. In a specific exemplary embodiment, a typical dopant concentration range may be from 1·10^{˜}to 1·10²¹ atoms/cm³, resulting in a resistivity range of 5·10⁻² to 5·10⁻⁴ ohm-cm.

With either dopant type, another advantage is realized in that the uniformity of the dopant material within the in-situ doped layer 215A is much more uniform than found in the prior art since the dopant and the semiconductor layer are deposited simultaneously. The prior art requires post-deposition doping by a high energy implant step followed by a high temperature anneal to activate the implant. Such techniques preclude a uniform dopant distribution within the contact area.

In a specific exemplary embodiment, the base substrate 201 and associated film stack may be annealed after depositing the in-situ doped layer 215A. The post-deposition anneal step will partially drive-in the concentration of dopant material into the base substrate, thus increasing the conductivity between the base substrate 201 and the in-situ doped layer 215A. Further, dopant in the bulk of the contact layer is activated during the anneal step, thus making the bulk electrically active. The anneal may be accomplished by a much shorter and lower temperature anneal step than required under the prior art.

Following the deposition of the in-situ doped layer 215A and any subsequent anneal step, a contact definition step forms the in-situ doped layer 215A into a suitable electrode contact for subsequent fabrication steps. Alternatively, the in-situ doped layer 215A may be defined prior to any anneal step.

For example, in a specific exemplary embodiment shown in FIG. 2H, the in-situ doped layer 215A has been patterned and etched into an etched contact electrode 215B. Such patterning and etching steps are known in the art. Etching may be accomplished through various dry or wet etch methods described above. In another exemplary embodiment shown in FIG. 2I, the in-situ doped layer 215A has been planarized by, for example, chemical mechanical planarization (CMP) to form a planarized contact electrode 215C.

Following contact definition, conventional fabrication techniques may be employed for completion of a plurality of electronic device types. The electrode formation techniques described allows easy and direct access to subsequently formed layers through upper level etches and metallization procedures known in the art. The additional metal layers allow direct contact with the base substrate 201 to a topside layer (not shown) of a completed electronic device.

In the foregoing specification, the present invention has been described with reference to specific embodiments thereof. It will, however, be evident to a skilled artisan that various modifications and changes can be made thereto without departing from the broader spirit and scope of the invention as set forth in the appended claims. For example, skilled artisans will appreciate that various types of dielectric layers or stacks of dielectric layers may be employed and various other types of semiconducting materials may be employed in the SOI contact formation process. Additionally, the techniques described herein may be applicable to other types of substrates and active semiconducting layers (e.g., various other elemental and compound semiconductors). Techniques to form various dielectric and semiconductor layers may be implemented in a variety of process tools such as, for example, those tools used in atomic layer deposition (ALD), chemical vapor deposition (CVD), low-pressure CVD (LPCVD), plasma-enhanced CVD (PECVD), or plasma-assisted CVD (PACVD). The specification and drawings are, accordingly, to be regarded in an illustrative rather than a restrictive sense.

What is claimed is:

1. A method of forming an electrical contact with a base substrate, the method comprising:
providing the base substrate having a first conductivity type, the base substrate having a dielectric layer and an active semiconductor layer formed thereon, the dielectric layer arranged to electrically insulate the active semiconductor layer from the base substrate;
forming a first masking layer over an uppermost surface of the active semiconductor layer, the uppermost surface being distal to the dielectric layer;
patterning a window on the first masking layer;
etching a first opening through the first masking layer to the underlying active semiconductor layer within an area defined by the window;
etching a second opening through an exposed region of the active semiconductor layer to the dielectric layer within the area defined by the window;
etching a third opening through an exposed region of the dielectric layer to the base substrate; and
simultaneously filling the first, second, and third openings with a semiconductor contact material while adding a dopant to the semiconductor contact material, the dopant having the first conductivity type, the semiconductor contact layer being in electrical contact with the base substrate.

2. The method of claim 1 further comprising cleaning the first, second, and third openings and an exposed portion of the base substrate prior to the filling step.

3. The method of claim 1 further comprising planarizing the semiconductor contact material to be approximately coplanar with an uppermost surface of the first masking layer.

4. The method of claim 1 further comprising:
forming a second mask layer over an uppermost surface of the semiconductor contact material;
patterning a contact area on the second mask layer;
etching the contact area of the second mask layer and the underlying semiconductor contact material to a level of an uppermost surface of the first masking layer.

5. The method of claim 1 further comprising:
forming a dielectric material on exposed sidewalls of the etched active semiconductor layer, the dielectric material electrically insulating the active semiconductor layer from the semiconductor contact material; and
removing any of the dielectric material from an uppermost portion of the base substrate.

6. The method of claim 1 further comprising forming a dielectric spacer on at least exposed sidewalls of the etched active semiconductor layer, the dielectric material electrically insulating the active semiconductor layer from the semiconductor contact material.

7. The method of claim 1 further comprising annealing the semiconductor contact material to partially drive-in the dopant material into an area of the base substrate underlying the area defined by the window.

8. The method of claim 7 further comprising electrically activating the base substrate through the annealing step.

9. The method of claim 1 wherein the semiconductor contact material is in electrical communication with the active semiconductor layer.

10. The method of claim 1 wherein the active semiconductor layer is selected to be comprised of a material having the first conductivity type.

11. A method of forming an electrical contact with a base substrate in a silicon-on-insulator material, the method comprising:
forming a first masking layer over an uppermost surface of an active semiconductor layer, the active semiconductor layer being an uppermost portion of the silicon-on-insulator material and having a first conductivity type;
patterning a window on the first masking layer;
etching a first opening through the first masking layer to the active semiconductor layer within an area defined by the window;
etching a second opening through an exposed region of the active semiconductor layer to a dielectric layer within the area defined by the window, the dielectric layer being a second portion of the silicon-on-insulator material;
etching a third opening through an exposed region of the dielectric layer to a base substrate of the silicon-on-insulator material, the base substrate having the first conductivity type; and
simultaneously filling the first, second, and third openings with a semiconductor contact material while adding a dopant to the semiconductor contact material, the dopant having the first conductivity type, the semiconductor contact layer being in electrical contact with the base substrate.

12. The method of claim 11 further comprising cleaning the first, second, and third openings and an exposed portion of the base substrate prior to the filling step.

13. The method of claim 11 further comprising planarizing the semiconductor contact material to be approximately coplanar with an uppermost surface of the first masking layer.

14. The method of claim 11 further comprising:
forming a second mask layer over an uppermost surface of the semiconductor contact material;
patterning a contact area on the second mask layer;
etching the contact area of the second mask layer and the underlying semiconductor contact material to a level of an uppermost surface of the first masking layer.

15. The method of claim 11 further comprising:
forming a dielectric material on exposed sidewalls of the etched active semiconductor layer, the dielectric material electrically insulating the active semiconductor layer from the semiconductor contact material; and removing any of the dielectric material from an uppermost portion of the base substrate.

16. The method of claim 11 further comprising forming a dielectric spacer on at least exposed sidewalls of the etched active semiconductor layer, the dielectric material electrically insulating the active semiconductor layer from the semiconductor contact material.

17. The method of claim 11 further comprising annealing the semiconductor contact material to partially drive-in the dopant material into an area of the base substrate underlying the area defined by the window.

18. The method of claim 17 further comprising electrically activating the base substrate through the annealing step.

19. The method of claim 11 wherein the semiconductor contact material is in electrical communication with the active semiconductor layer.

20. A method of forming an electrical contact with a base substrate in a silicon-on-insulator material, the method comprising:
forming a first masking layer over an uppermost surface of an active semiconductor layer, the active semiconductor layer being an uppermost portion of the silicon-on-insulator material;
patterning a window on the first masking layer;
etching a first opening through the first masking layer to the active semiconductor layer within an area defined by the window;
etching a second opening through an exposed region of the active semiconductor layer to a dielectric layer within the area defined by the window, the dielectric layer being a second portion of the silicon-on-insulator material;
etching a third opening through an exposed region of the dielectric layer to a base substrate of the silicon-on-insulator material, the base substrate having the first conductivity type; and
simultaneously filling the first, second, and third openings with a semiconductor contact material while adding a dopant to the semiconductor contact material, the dopant having the first conductivity type, the semiconductor contact layer being in electrical contact with the base substrate.

21. The method of claim 20 further comprising cleaning the first, second, and third openings and an exposed portion of the base substrate prior to the filling step.

22. The method of claim 20 further comprising:
forming a dielectric material on exposed sidewalls of the etched active semiconductor layer, the dielectric material electrically insulating the active semiconductor layer from the semiconductor contact material; and removing any of the dielectric material from an uppermost portion of the base substrate.

23. The method of claim 20 further comprising annealing the semiconductor contact material to partially drive-in the dopant material into an area of the base substrate underlying the area defined by the window.

24. The method of claim 23 further comprising electrically activating the base substrate through the annealing step.

25. The method of claim 20 wherein the semiconductor contact material is in electrical communication with the active semiconductor layer.

26. The method of claim 20 wherein the active semiconductor layer is selected to be comprised of a material having the first conductivity type.
